(19) United States
(12) Patent Application Publication
(10) Pub. No.: US 2026/0181742 A1
(43) Pub. Date: Jun. 25, 2026

(54) Electric Heating Device and Method for Producing the Same

(71) Applicant: Eberspächer catem GmbH & Co., Herxheim (DE)

(72) Inventors: Patrick Werner, Neuhofen (DE); Timo Kröner, Rülzheim (DE); Michael Niederer, Kapellen-Drusweiler (DE); Rüdiger Freitag, Landau (DE)

(21) Appl. No.: 19/429,056

(22) Filed: Dec. 22, 2025

(30) Foreign Application Priority Data
Dec. 23, 2024 (DE) 102024139652.0

(51) Int. Cl. H05B 3/04; H05B 3/00; H05K 5/02; H05K 5/04

(52) U.S. Cl. CPC H05B 3/04; H05B 3/0014; H05K 5/04; H05B 2203/02; H05K 5/0247

(57) ABSTRACT

An electric heating device, in particular for a motor vehicle, includes a housing that is at least partially electrically conductive with a circumferential groove provided on its front side, and a cover formed from sheet metal, which closes the housing and engages with a circumferential edge in the groove, which contains a sealing agent. To increase the sealing of the housing while reliably shielding the electrical components housed therein, the circumferential edge has a first leg engaging in the groove and a second leg bent away from it extending therefrom, which is in electrically conductive contact with one of the boundary walls of the groove. In the method for producing the electrical heating device, the circumferential edge is inserted in the groove and a sealing agent then is introduced into the groove, which hardens in the groove.

### BACKGROUND INFORMATION

### 1. Field of the Invention

The present invention relates to an electric heating device and a method for its producing. An electric heating device known from DE 20 2020 000 689 U1 is considered to be generic. This prior art discloses an electric heating device with an at least partially electrically conductive housing and a cover made of sheet metal, which closes the housing and covers the housing opening.

### 2. Background of the Invention

The present invention relates in particular to an electric heating device in which the housing has a heating chamber with inlet and outlet openings for a fluid to be heated, a heating device connected to the heating chamber in a thermally conductive manner, which can be designed as a thick-film heating device or as a PTC heating device and can be electrically connected in a connection chamber. A partition wall usually separates the heating chamber from the connection chamber in a fluid-tight manner.

In the electrical heating device according to the invention, several PTC heating devices can be accommodated in the housing. Thus, several PTC heating devices are usually electrically connected in the connection chamber, possibly also grouped into heating circuits. For this purpose, a printed circuit board may be provided in the connection chamber, which assigns different PTC heating devices to different heating circuits. A populated printed circuit board may also be provided in the connection chamber, which is a central component of a control device with which the heating device is controlled for appropriate power adjustment of the electric heating device.

The heating device is usually located on one side of the partition wall, while a control device is usually located on the other side.

These details are also known from DE 20 2020 000 689 U1.

The above-mentioned features may also be preferred features of the electrical heating device according to the invention.

With corresponding electrical heating devices, there is the problem of interference from electromagnetic waves affecting other components in the vicinity, particularly when switching the PTC heating device. In a vehicle, for example, these components may include electronic components or components of the on-board entertainment system. In view of this, it is known to design the housing to be at least partially electrically conductive for the purpose of shielding. Electrical contact is not only implemented for EMC reasons, but also in particular for high-voltage safety (ground connection). Otherwise, electrical potential could abut the cover and this could not be detected by the insulation monitoring. In particular, the connection chamber and the control device provided therein are housed in a metal housing. Parts of the housing surrounding or defining the heating chamber may be made of an electrically non-conductive material. Plastic is preferred in order to reduce weight.

The requirements for an electric heating device in a motor vehicle in particular impose various additional requirements. For example, the electric heating device must not only be designed to be as lightweight as possible. Rather, the electrical components of the electrical heating device should be reliably protected from the environment. This applies in particular to electrical heating devices for electromobility. These electrical heating devices are usually operated at high voltage. Moisture and/or contamination that penetrates the connection chamber, for example, can impair the desired electrical insulation of individual components. Contaminated or moistened surfaces can promote the formation of leakage currents.

### SUMMARY OF THE INVENTION

The present invention is based on the problem of specifying an electric heating device and a method for producing it which enable the best possible sealing of the housing while reliably shielding the electrical components housed therein.

To solve this problem, the present invention specifies an electric heating device of the type mentioned above, in which the housing has a circumferential groove on one end face. A circumferential groove in this sense is understood to be a groove that is formed circumferentially in the circumferential direction of the groove. It is not important that the groove is formed with the same depth over the entire circumference. A sealing agent is applied to the groove to seal it around its entire circumference. The cover has a circumferential edge that engages with the groove in such a way that the edge of the cover is immersed in the sealing agent around its entire circumference. This results in a completely fluid-tight seal of the cover in the area of the groove. An adhesive, in particular a hardening adhesive that remains elastic even when hardened, is particularly suitable as a sealant. For example, a silicone adhesive can be used.

The adhesive can promote the retention of the cover on the housing due to its adhesive effect. However, the adhesive can also serve only as a sealing compound that prevents the passage of contamination and/or moisture in the area of the groove by absorbing the surrounding edge into the adhesive and thus connecting it.

The cover may be a sheet metal cover. This wording conveys that the material of the cover has a wall thickness predetermined by the raw material of the sheet metal. The cover may be provided by punching and bending or other forming processes in such a way that a surrounding edge and/or additional contact tabs on the edge protrude essentially at right angles from a cover surface formed by the cover from the otherwise basically flat cover surface of the cover.

The adhesive may be applied to the groove in volumetric doses. The adhesive is usually applied after the cover has been connected to the housing, usually by pressing it into place. In this way, the adhesive also protects the contact locations for the electrical connection of the cover to the housing from external influences. The adhesive may be applied alone into a gap between an inner surface delimiting the groove and the surrounding edge of the cover. This allows the amount of adhesive to be kept to a minimum.

Corrosion at the contact location is not a concern due to the sealing effect of the adhesive, so that a secure electrical connection between the cover and the housing is maintained even over a longer period of use of the electric heating device. In addition, there is an improved connection between the cover and the housing, since not only is the cover or contact tab mechanically clamped in the groove, but it is also secured in the groove by an at least partially cured adhesive and its adhesive properties.

The adhesive usually extends in the height direction of the groove to beyond a free outer end of the edge of the cover, which, according to the present invention, is formed by an outwardly bent outer leg that protrudes outwardly from an inner leg of the edge. Depending on the product requirements, the filling height can thus be flexibly varied and adjusted.

The surrounding edge has a first leg that engages in the groove and a second leg that extends from it. The first leg usually extends from a lid surface; the second leg is connected to the first leg via a bending area. The first leg and the second leg are usually arranged in a V-shape relative to each other, with the bend area located opposite the bottom of the groove and usually forming the deepest engagement in the groove.

The first leg is usually an inner leg, while the second leg is usually an outer leg. The first leg interacts with an inner boundary wall of the groove; the second leg interacts with an outer boundary wall of the groove.

Outside and inside preferably refer to the corresponding areas relative to the interior of the housing. The outer leg is therefore regularly further away from the interior of the housing than an inner leg of the edge. However, the outer leg and the outer boundary wall provided for it can also be formed by the areas of the groove and edge closer to the interior of the housing. In this variant, the inner leg and the inner boundary wall provided for it are further away from the interior of the housing than the outer leg and the outer boundary wall.

One leg, possibly the outer leg, contacts the associated boundary wall of the groove in an electrically conductive manner, for which purpose the outer leg is usually applied with preload against the outer boundary wall. This contact location should be covered by the sealant or adhesive to provide the best possible corrosion protection. The inner leg of the edge is arranged within the groove and is usually supported by the inner boundary wall of the groove.

The housing forming the groove may be a die-cast part. The circumferential edge according to the present invention has two legs which form a bending area between them. In an unstressed state, the maximum distance between the two legs, possibly the inner surface of the inner leg and the outermost surface of the outer leg, is greater than the width of the groove. In the unstressed state, one leg, possibly the outer leg, usually protrudes diagonally outwards and upwards from the curved bending area. The circumferential edge thus possibly has a funnel-shaped geometry that widens outwards in cross-section. This means that when the circumferential edge is inserted into the groove, the edge is elastically clamped within the groove.

Usually, an assembly tool is inserted from above into the bending area and the upwardly open circumferential edge and presses the bending area and thus the circumferential edge completely into the circumferential groove of the housing. The bending area allows for increased bending, especially of the outer leg, which usually interacts with the outer boundary wall on the inside with a sharp-edged outer end section and interlocks with it. This also prevents the cover from being lost on the housing. The elastic preload between the outer leg and the inner leg reinforces this locking action by interlocking. The elastic preload is generated and maintained in particular in the bending area. The bending area can be reinforced by embossing the sheet metal material, thereby achieving increased strength, which increases the preload force holding the edge in the groove. The embossing is distributed in the circumferential direction, possibly immediately adjacent to a hook formed by the two legs and/or within such a hook.

It is understood that the said preload may be counteracted by the inner leg and its support against the inner boundary wall of the groove. This usually extends in the height direction of the groove. While the outer boundary wall usually has a flat inner surface in the height direction, over which the outermost end section slides when the circumferential edge is inserted into the groove, the inner boundary wall may be thinner in its upper region than in the lower region, with a certain sloping surface between the two regions. This design facilitates the insertion of the circumferential groove under preload and reinforces the interlocking at the end of the assembly movement by narrowing the groove on the one hand and by creating a thickened inner wall which opposes the elastic tension of the circumferential edge in the groove with increased resistance.

To reduce the mechanical stress on the housing, a preferred further development of the present invention proposes that the circumferential edge be provided only in sections on the outer boundary wall in the circumferential direction of the groove. Accordingly, elastic interlocking occurs only in sections, thus reducing the mechanical stress on the walls of the housing that delimit the groove.

In addition, the housing can form webs that extend through the groove, which are provided in sections and connect the outer boundary wall of the groove to the inner boundary wall, thus improving the strength of the groove. The webs allow for a relatively thin-walled design of the walls bordering the groove despite the elastic tensioning of the surrounding edge within the groove, as the webs brace and stiffen the groove transversely. The webs usually protrude above the base of the groove in the vertical direction by an amount that is at least 40 percent, possibly at least 50 percent, of the height of the groove. The height of the groove is determined by the distance between the groove base and the boundary wall of the groove with the lowest height. The boundary walls of the groove may have the same height on the inside and outside. However, with a view to improved electrical contact and sealing, as well as a compact design of the present invention, it is preferable to form the outer boundary wall higher than the inner boundary wall. The cover may be designed so that it rests on the inner boundary wall.

The design also offers the possibility of arranging the cover surface formed by the cover and essentially covering the housing so that it is not higher than the upper edge of the outer boundary wall. The outer boundary wall can extend beyond the cover surface and, accordingly, enable the electrical heating device to be stored on the front edge surface of the outer leg during transport after manufacture. Accordingly, the electric heating device does not have to be supported by the relatively thin-walled cover surface during transport. The cover possibly rests on top of the inner boundary wall.

At the level of the webs intersecting the groove, the surrounding edge possibly has an inner leg stub and ends there with the inner leg stub. This means that at the level of the webs, there is no outer leg that interacts with the outer boundary wall, which results in mechanical relief for the outer boundary wall. The leg stub can end at the inner boundary wall at the level of, or slightly above, the aforementioned inclined surface. The leg stub can be wider in the direction of the groove than the web covered by the leg stub. A leg stub can also extend over two webs spaced apart from each other.

According to the method of the invention, the surrounding edge is first inserted into the groove and only then is the sealing agent, for example in the form of an adhesive, introduced, usually in liquid form, possibly dosed, into the groove to seal the surrounding edge. Dosing is usually volumetric to ensure that the sealant does not run beyond the boundaries of the groove: the cover resting on the inner boundary wall also prevents unwanted seepage of the sealant into the interior of the housing.

The amount of adhesive may be adjusted so that it does not fill the entire groove, but rather a smaller volume of a gap formed between the outer wall of the groove and the inner leg.

### BRIEF DESCRIPTION OF THE DRAWINGS

Further details and advantages of the present invention are apparent from the following description of an embodiment in conjunction with the drawing. This shows:

FIG. 1 a perspective exploded view of an embodiment of an electric heating device;

FIG. 2 a longitudinal sectional view of a heating device using the example of a PTC heating device;

FIG. 3 a perspective top view of a cover mounted on the housing;

FIG. 4 a perspective cross-sectional view of the groove and the edge of the cover for the example shown in FIG. 3; and

FIG. 5 an enlarged cross-sectional view of the groove and the edge of the cover for the example shown in FIGS. 3 and 4.

### DETAILED DESCRIPTION

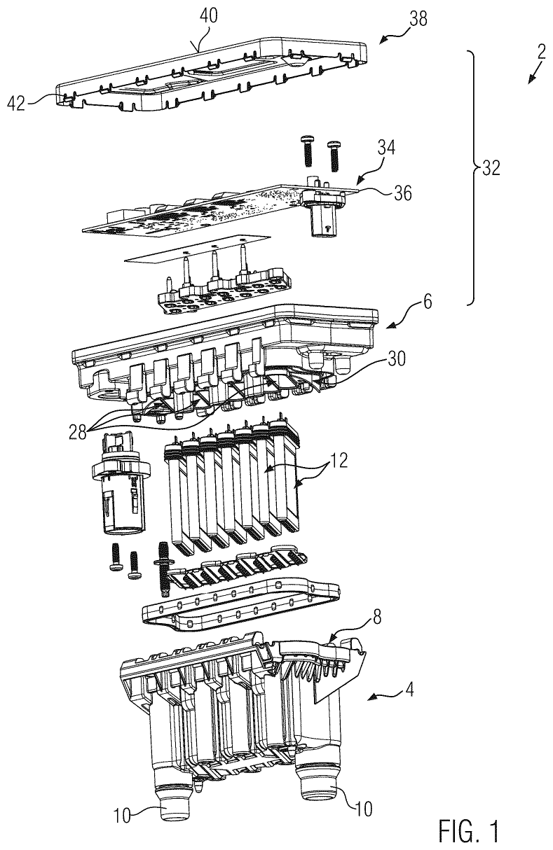

FIG. 1 shows an example of an electric heating device 2 with a multi-part heater housing, which comprises a housing lower part 4 made of plastic and a housing upper part 6 made of metal in one piece by die casting.

The lower housing part 4 is trough-shaped and encloses a heating chamber 8 and forms inlet and outlet connections 10 that communicate with the heating chamber 8. These inlet and outlet connections 10 are formed integrally with the lower housing part 4 by injection molding. Several heating devices 12 are shown between the upper part of the housing 6 and the lower part of the housing 4.

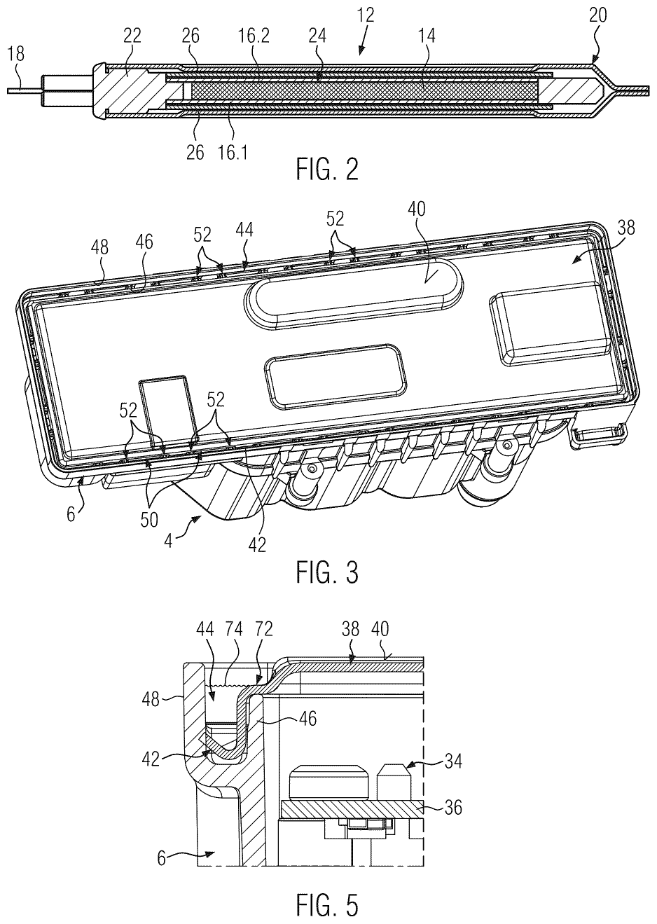

As FIG. 2 illustrates, these heating devices 12 each have at least one PTC element 14, to which contact elements 16.1; 16.2 abut, which form contact tongues 18 that protrude from a metal housing 20. The PTC element 14 is housed in a frame 22 and between the contact elements 16.1; 16.2. Insulating layers 26 are provided between the metallic housing 20 and a heating cell 24 formed by the two contact elements 16.1; 16.2 and the PTC element 14.

The heating devices 12 are held in a plug-in contact manner in a receptacle 28 provided for this purpose in a partition wall 30 of the upper part 6 of the housing and are electrically connected in a connection chamber 32 which accommodates a control device 34 controlling the heating devices 12, the essential component of which is formed by a printed circuit board 36. Details of this design are described in EP 3 334 242 A1, which was filed by the applicant.

The upper part of the housing 6 is connected in a sealing and electrically conductive manner to a cover 38, the cover surface 40 of which covers the connection chamber 32 and is essentially flat. The upper part of the housing 6 thus forms, for example, the housing according to claim 1 and is hereinafter referred to simply as housing 6.

As FIGS. 3 to 5 illustrate, the cover 38 has a circumferential edge 42 that engages in a circumferential groove 44 of the housing 6. The groove 44 is bounded on the inside by an inner boundary wall 46 and on the outside by an outer boundary wall 48 of the housing 6 and has a groove base 50 provided between them, which is interspersed with webs 52 in sections in the circumferential direction of the groove 44. The circumferential edge 42 has an inner leg 54, which extends substantially parallel to the inner boundary wall 46, and an outer leg 56, which is directed obliquely outwards and away from the groove base 50 by bending the sheet metal material forming the cover 38.

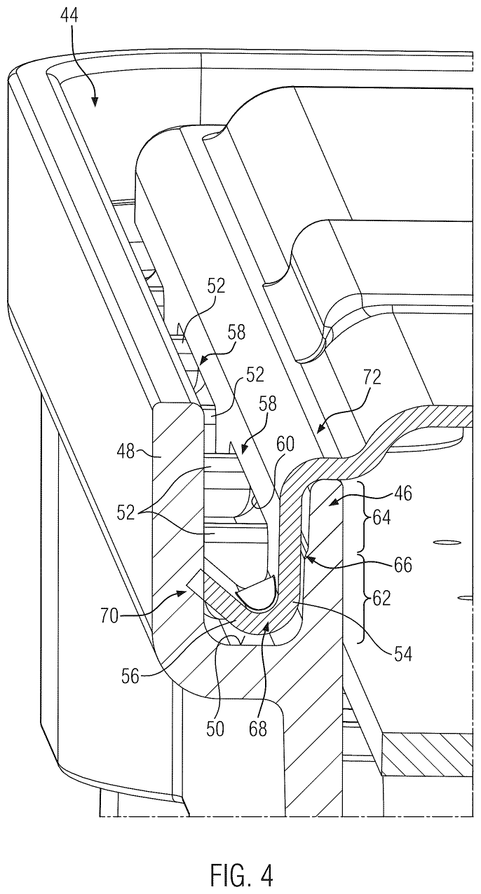

At the level of the webs 52, the circumferential edge 42 ends with an inner leg stub 58. As shown in FIGS. 4 and 5, the inner boundary wall 46 has a slightly stepped profile with a widened lower section 62, an upper section 64 of reduced thickness above it, and an inclined surface 66 between them, which is located in the area of the free end 60 and between the webs 52 associated with the leg stub 58, so that sealant subsequently introduced into the groove 44 can also reach between the inner leg 54 and the inner boundary wall 46 and act as a seal there.

A bending area of the circumferential edge 62, marked with reference numeral 68, is arranged at a distance from the groove base 50 in the height direction, so that the circumferential edge 42 can move freely and elastically in the bending area 68. Reference numeral 69 indicates an embossing applied from the outside against the bending area 68, which stiffens the inner leg 54 relative to the outer leg 56. This provides sufficient clamping forces to secure the cover 38 in the groove 44. In the end position shown in FIG. 4, the front tip or, if applicable, the slightly rounded end of an outermost end section 70 of the outer leg 56 engages with the outer boundary wall 48 and thus secures the end position of the circumferential edge 42 and thus of the cover 38 relative to the housing 6.

As FIGS. 4 and 5 illustrate, the inner boundary wall 46 is less high than the outer boundary wall 58. The assembled cover 38 shown in FIGS. 4 and 5 rests with its section marked with reference numeral 72 on the free end of the inner boundary wall 64. The cover surface 40 lies lower overall than the upper free end of the outer boundary wall 48.

During assembly, the circumferential edge 42 of the cover 38 is positioned above the groove 44. A tool (not shown) essentially engages the bending area 68 of the circumferential edge 42 and presses the cover 38 into the groove 44. In the process, the bending area 68 is further curved, while the outer leg 56, which is initially oversized relative to the width of the groove 44, protrudes outward from it, is elastically applied against the inner boundary wall 46, and slides down it. As the insertion movement progresses, during which the inner leg 54 is supported by the inner boundary wall 46, the outer convex curvature of the bending area 68 hits the inclined surface 66, further increasing the elastic tension of the surrounding edge 42. The insertion movement or the press-in process is completed when the cover 38 is applied with its resting section 72 to the inner boundary wall 46.

After that, a sealing agent, for example an adhesive, is distributed volumetrically and circumferentially into the circumferential groove 44 between the inner leg 54 and the inner boundary wall 46. The adhesive is indicated by reference numeral 74 in FIG. 4. The filling level of the adhesive 74 is above the inclined surface 66. In the embodiment shown here, the adhesive 74 extends within the groove 44 approximately up to the bearing section 72.

The present invention requires a certain groove depth. The sealant 74, which completely or partially fills the groove 44, results in an extended creep path. The finished electric heating device 2 can be placed on the outer boundary wall 48 during producing or storage, as this protrudes beyond the cover 38 as a whole. This prevents the surrounding edge 42 from moving relative to the groove 44, which could impair the connection of the surrounding edge 42 to the sealing material 74 and thus the tightness. Incidentally, the supporting section 72 rests on the inner boundary wall 46. These webs 52 are distributed in the circumferential direction so that the cover 38 is supported in the circumferential direction of the groove 44. This also protects the bond with the sealing agent 74 and increases the tightness. The outer legs 56 lie between the inner leg stubs 58 in the circumferential direction in sections on the outer boundary wall 48 and thus interlock with it. The elastic tensioning of the surrounding edge 42 in the groove 44 secures the connection between the cover 38 and the housing 6.

1. An electrical heating device comprising:
a housing that is at least partially electrically conductive, wherein a circumferential groove is provided on an end face of the housing; and
a cover which is formed from sheet metal, wherein the cover closes the housing and has a circumferential edge that engages in the groove, wherein the groove contains a sealing agent, and wherein the circumferential edge of the cover has a first leg that engages in the groove and a second leg that is bent away from the groove.

2. The electrical heating device according to claim 1, wherein at least one of the legs is in electrically conductive contact with a boundary wall of the groove.

3. The electrical heating device according to claim 1, wherein at least one of the legs is interlocked with at least one boundary wall of the groove.

4. The electrical heating device according to claim 3, wherein at least an outer leg is interlocked with an outer boundary wall of the groove.

5. The electrical heating device according to claim 1, wherein at least one of the legs is applied under elastic preload to at least one boundary wall of the groove.

6. The electrical heating device according to claim 5, wherein an outer leg is applied under elastic preload to an outer boundary wall of the groove.

7. The electrical heating device according to claim 5, wherein the preload is counteracted by supporting one of the legs against one of the boundary walls of the groove.

8. The electrical heating device according to claim 6, wherein the preload is counteracted by supporting an inner leg against an inner boundary wall of the groove.

9. The electrical heating device according to claim 1, wherein the circumferential edge only abuts in sections in a circumferential direction against a boundary wall of the groove.

10. The electrical heating device according to claim 5, wherein the circumferential edge only abuts in sections in a circumferential direction against an outer boundary wall of the groove.

11. The electrical heating device according to claim 6, wherein the circumferential edge only abuts in sections in a circumferential direction against an outer boundary wall of the groove.

12. The electrical heating device according claim 1, wherein the housing forms
webs passing through the groove, and wherein the circumferential edge of the housing ends with an inner stub located at a level of the webs

13. The electrical heating device according to claim 1, wherein an outer boundary wall of the groove protrudes beyond an inner boundary wall of the groove, and wherein the cover rests on the inner boundary wall of the groove.

14. The electrical heating device according to claim 1, wherein a cover surface that covers the housing protrudes beyond a section of the cover resting on an inner boundary wall of the groove.

15. A method for producing an electric heating device comprising:
inserting a circumferential edge of a sheet metal cover in a circumferential groove provided on and end face of an at least partially electrically conductive housing to close the housing; and then,
applying a sealing compound to the groove, which hardens in the groove.

16. The method according to claim 15, wherein, during the inserting, a first leg on the circumferential edge engages in the groove and a second leg that is bent away from the first leg is placed into electrically conductive contact with a boundary wall of the groove
